(19) United States
(12) Patent Application Publication
(10) Pub. No.: US 2024/0194270 A1
(43) Pub. Date: Jun. 13, 2024

(54) DEBIASING SCHEME FOR PARTIAL BLOCK ERASE BASED ON WORD LINE GROUPS

(71) Applicant: Micron Technology, Inc., Boise, ID (US)

(72) Inventors: Qun Su, Boise, ID (US); Pitamber Shukla, Boise, ID (US); Ryan Hrinya, Boise, ID (US); Fulvio Rori, Boise, ID (US); Jose Nino N. Monje, Boise, ID (US)

(21) Appl. No.: 18/528,337

(22) Filed: Dec. 4, 2023

Related U.S. Application Data
(60) Provisional application No. 63/430,922, filed on Dec. 7, 2022.

(51) Int. Cl. G11C 16/16; G11C 16/04; G11C 16/08

(52) U.S. Cl. CPC G11C 16/16; G11C 16/0483; G11C 16/08

(57) ABSTRACT

A method includes determining that a first group of word lines associated with a block of memory cells are in a programmed state and determining that a second group of word lines associated with the block of memory cells are in an unprogrammed state. The method further includes applying a first debiasing voltage to the first group of word lines based on the determination that the first group of word lines are in the programmed state and applying a second debiasing voltage to the second group of word lines based on the determination that the second group of word lines are in the unprogrammed state.

### PRIORITY INFORMATION

This application claims the benefit of U.S. Provisional Application No. 63/430,922, filed on Dec. 7, 2022, the contents of which are incorporated herein by reference.

### TECHNICAL FIELD

Embodiments of the disclosure relate generally to memory sub-systems, and more specifically, relate to application of a debiasing scheme for partial block erase based on word line groups.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system in accordance with some embodiments of the present disclosure.

FIG. 2 illustrates an example of a memory device coupled to a debiasing circuitry component in accordance with some embodiments of the present disclosure.

FIG. 3 illustrates another example of a memory device coupled to debiasing circuitry in accordance with some embodiments of the present disclosure.

FIG. 4 illustrates an example flow diagram corresponding to a debiasing scheme for partial block erase based on word line groups in accordance with some embodiments of the present disclosure.

FIG. 5 is a flow diagram corresponding to a method for a debiasing scheme for partial block erase based on word line groups in accordance with some embodiments of the present disclosure.

FIG. 6 is a block diagram of an example computer system in which embodiments of the present disclosure may operate.

### DETAILED DESCRIPTION

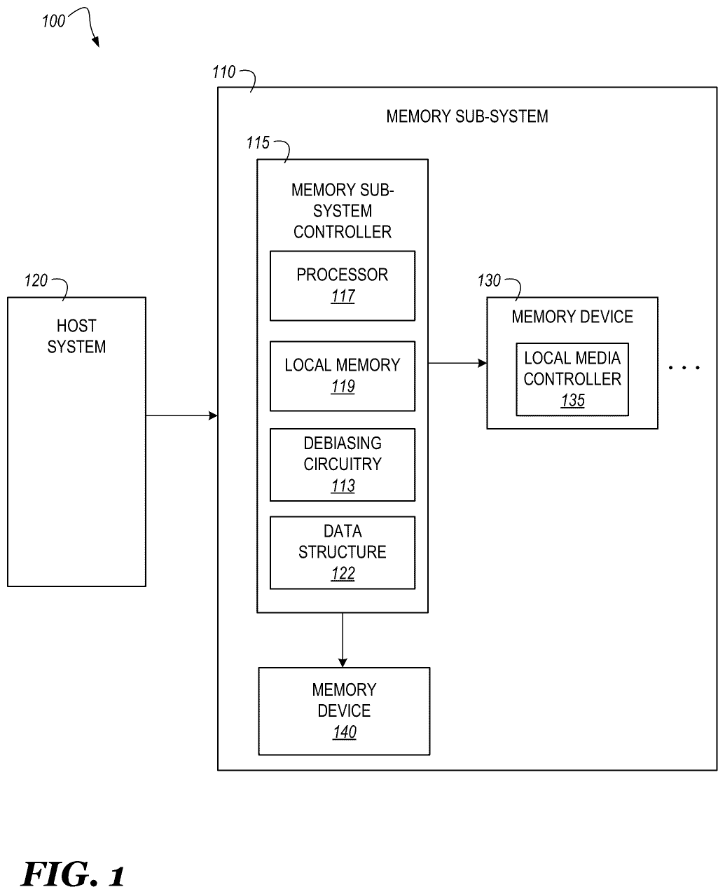

Aspects of the present disclosure are directed to a debiasing scheme for partial block erase based on word line groups in a memory sub-system, in particular to memory sub-systems that include circuitry to control application of a debiasing voltage to multiple word line groups. A memory sub-system can be a storage system, storage device, a memory module, or a combination of such. An example of a memory sub-system is a storage system such as a solid-state drive (SSD). Examples of storage devices and memory modules are described below in conjunction with FIG. 1, et alibi. In general, a host system can utilize a memory sub-system that includes one or more components, such as memory devices that store data. The host system can provide data to be stored at the memory sub-system and can request data to be retrieved from the memory sub-system.

A memory device can be a non-volatile memory device. One example of non-volatile memory devices is a NOT-AND (NAND) memory device (also known as flash technology). Other examples of non-volatile memory devices are described below in conjunction with FIG. 1. A non-volatile memory device is a package of one or more dice. Each die can consist of one or more planes. Planes can be grouped into logic units (LUN). For some types of non-volatile memory devices (e.g., NAND devices), each plane consists of a set of physical blocks. Each block consists of a set of pages. Each page consists of a set of memory cells (“cells”). A cell is an electronic circuit that stores information. A block hereinafter refers to a unit of the memory device used to store data and can include a group of memory cells, a word line group, a word line, or individual memory cells. For some memory devices, blocks (also hereinafter referred to as “memory blocks”) are the smallest area that can be erased. Pages cannot be erased individually, and only whole blocks can be erased.

Each of the memory devices can include one or more arrays of memory cells. Depending on the cell type, a cell can store one or more bits of binary information, and has various logic states that correlate to the number of bits being stored. The logic states can be represented by binary values, such as “0” and “1”, or combinations of such values. There are various types of cells, such as single level cells (SLCs), multi-level cells (MLCs), triple level cells (TLCs), and quad-level cells (QLCs). For example, a SLC can store one bit of information and has two logic states.

Some NAND memory devices employ a floating-gate architecture in which memory accesses are controlled based on a relative voltage change between the bit line and the word lines. Other examples of NAND memory devices can employ a replacement-gate architecture that can include the use of word line layouts that can allow for charges corresponding to data values to be trapped within memory cells based on properties of the materials used to construct the word lines. While both floating-gate architectures and replacement-gate architectures employ the use of select gates (e.g., select gate transistors), replacement-gate architectures can include multiple select gates coupled to a string of NAND memory cells. Further, replacement-gate architectures can include programmable select gates.

The pages of memory cells of, for example, a NAND memory device can be arranged in a row and have a bit line structure that connects into a memory “address” called a word line. The address provides a means of identifying a location for data storage, and the word line forms an electrical path allowing all the memory cells on that row to be activated at the same time for storage (“write”) or retrieval (“read”). A set of memory cells (e.g., a page of memory cells or multiple pages of memory cells) that are coupled to a particular word line or to a set of particular word lines can be referred to herein as a “word line group” or a “page of memory cells of a word line group.” In the alternative, a word line group can be described as comprising or including one or more pages or sets of memory cells.

Due to the characteristics of memory cells, and, more specifically, the inherent characteristics of non-volatile memory cells (e.g., NAND memory cells), a quality of such memory cells generally degrade over time. This degradation in quality can be based on a quantity of program-erase cycles (PECs) experienced by the memory cells, a frequency that data is written to or read from the memory cells, an amount of time that data written to the memory cells is stored by the memory cells, workloads experienced by the memory cells, operational temperatures of the memory cells, and/or process variations within the memory cells (or sets of the memory cells), among other factors that can contribute to degradation of such memory cells. This degradation of quality of the memory cells can give rise to errors involving data written to the memory cells, which can be costly to correct in terms of time, power consumption, and/or quality of service (QoS).

For example, the degradation of the quality of the memory cells and/or memory dice, chips, components, etc. of memory devices of a memory sub-system can lead to scenarios in which a threshold voltage (V_{T}) distribution of the memory cells and/or word line groups of a memory device can shift or “drift” over time based on the quality of the memory cells, word line groups, memory dice, etc. of the memory sub-system. That is, the V_{T} distribution of the memory cells and/or word line groups, etc. can change over time such that the actual V_{T} distribution corresponding to the memory cells and/or word line groups, etc. is different than the expected V_{T} distribution corresponding to the memory cells and/or word line groups, etc., which can lead to the introduction of errors in data that is written to and/or stored by memory cells accessible by word line groups of the memory device.

Further, and particularly when blocks of memory cells are partially programed, therefore leading to a “partial block” condition,” non-uniform V_{T} distributions across blocks of memory cells can arise thereby increasing the introduction of errors in data that is written to and/or stored by memory cells accessible by word line groups of the memory device and/or adding complications with respect to block handling techniques, such as error correction, read disturb and/or write disturb mitigation, raw bit error rate (RBER) mitigation, V_{T} distribution correction, and/or facilitation of data retention, among other such techniques. As used herein, the term “partial block,” and variants thereof, generally refers to a condition in which a block of memory cells is not fully programmed, i.e., a condition in which data is not written to or stored by memory cells corresponding to each and every word line associated with the block of memory cells. In a non-limiting example, a partial block (PB) occurs when data written to the block does not completely fill the block, which results in blank word lines being present in the block. Data in the PB is known to be more prone to error characteristics, such as voltage drifts, due to the presence of the blank word lines. In contrast to PB, a closed block condition occurs when data written to the block completely fills the block.

In general, memory sub-systems that include NAND memory devices can allow for blocks to be maintained in a partially programmed state (e.g., a state in which a partial block condition occurs) for an indefinite amount of time. Maintaining this state may be required in some approaches because subsequent memory accesses (e.g., data writes) into the remaining pages of a PB could result in a non-uniform V_{T} distribution across the block and, as described above, incur complications to the memory sub-system in handling the block. PB usage can be significant (in terms of time and/or resources) throughout the lifetime of a memory device, such as a NAND memory device, which can further exacerbate these and other complications. Further, replacement gate NAND technologies can invoke worse data retention on blocks that have been previously exposed to a PB condition and/or have experienced PB program/erase cycling (PB cycling) operations than NAND technologies that do not employ replacement gate architectures. This degraded data retention can be attributed to the unintended deep erased state from the PB cycling operation on the unprogrammed portion of the PB.

Some approaches attempt to mitigate the aforementioned issues and complications by performing operations to apply a debiasing voltage (e.g., a debiasing voltage level) to the word lines associated with the blocks to correct an amount of voltage applied to blocks via the word lines. Generally, such debiasing voltages are applied during an erase cycle of the block and may therefore be referred to herein as an “erase debiasing voltage” or “erase debiasing voltage level.” For convenience and simplicity, such approaches generally use the same debiasing voltage levels regardless of the program state of the block (i.e., regardless of whether the block is a PB or a full block). That is, previous approaches generally apply the same erase debiasing voltage to blocks and/or pages of unprogrammed memory cells via word lines as are applied to blocks and/or pages of programmed memory cells via word lines and, as a result, fail to make a distinction between pages of a PB and pages of a full block.

For example, some approaches inject holes (generally by injecting a positive charge) in the memory cells during an erase operation (e.g., and erase pulse) to mitigate and/or clear electrical charges that have accumulated in the memory cells and, therefore the block that includes such memory cells. However, to minimize accumulation of such holes and/or to prevent “over-erase” conditions in which debiasing voltages that are too large are applied to the memory cells (therefore inadvertently erasing data that was not intended to be erased), all of the word lines (or word line groups) may be subjected a non-zero debiasing voltage. This debiasing voltage is generally considered to be small (e.g., ˜0.5 V) relative to a voltage associated with the pillar (e.g., a pillar reference voltage) coupled to the word lines and can, in some approaches, be applied to groups of word lines as part of an operation to mitigate and/or clear electrical charges that have accumulated in the memory cells, such as a debiasing operation.

However, by applying the same non-zero debiasing voltage, for example, during performance of an erase operation, to all of the word lines (or word line groups) regardless of whether or not blocks coupled to the word lines are PBs or full blocks and/or whether a programmed word line and an unprogrammed word line are in a same word line group, such approaches may lead to increased degradation of the memory cells associated with a memory device as a whole, as mentioned above. That is, such approaches can ignore scenarios in which the block is only partially programmed (e.g., the block can be a partial block), and/or scenarios in which a programmed word line and an unprogrammed word line in the same word line group (or “segment”) may be exposed to the same debiasing voltage during erase pulse.

Further, such approaches can cause unprogrammed word lines (e.g., word lines that are associated with memory cells that do not have data written thereto) to be pre-programmed to a lower V_{T} value than programmed word lines (e.g., word lines that are associated with memory cells that have data written thereto) prior to performance of the erase operation, causing the pre-program operation to fail to create a V_{T} distribution similar to a normal program operation experienced by programmed word lines that are part of a full block. As a result, these approaches do not completely mitigate over erase issues caused by erasing an unprogrammed word line. Moreover, in operation, a memory sub-system may experience conditions in which multiple partial block program/erase could occur consecutively therefore driving the unprogrammed word lines to an even “deeper state.” That is, consecutive partial block program/erase cycles can fail to mitigate holes, which may therefore remain after traditional debiasing methodologies are employed. This can lead to erase states that are “deeper” due to the insufficient hole mitigation performed during erase cycles. In such scenarios, further writing of data into the block would incur additionally degraded data retention as a result of the accumulated holes contributing to increasing charge loss for the unprogrammed memory cells of a partial block. Moreover, the accumulated holes in such approaches can eventually lead to an increase in programming time (tPROG) for the memory cells that experience the aforementioned conditions.

For example, in some approaches, the default erase debiasing value may be set high enough to prevent an accumulation of holes, but not so high as to cause a shallow erase. This generally works as intended when the block is completely programmed, however such paradigms can lead to deeper erase condition when there are unprogrammed WL (e.g., in the case of PB condition). This can, in the case of a PB condition, lead to the debiasing voltage not being high enough to counteract the over erase that occurs when an erase operation is performed on an unprogrammed word line.

Aspects of the present disclosure address the above and other deficiencies by applying different debiasing voltages to different word line groups based on characteristics of the word line groups. In particular, embodiments herein allow for different debiasing voltages to be applied to word line groups that are associated with unprogrammed memory cells than are applied to word line groups that are associated with programmed memory cells (e.g., in response to detection of a partial block condition involving a block of memory cells). As described in more detail herein, over-erase issues that can arise in previous approaches (particularly over-erase issues that may be exacerbated when partial blocks are utilized and/or over-erase states that can arise as a result of back-to back PB cycling, etc.) can be mitigated while post-cycling data retention (e.g., program-erase cycling, PB cycling, etc.) in comparison to previous approaches and/or overall performance (e.g., a reduction in tPROG, RBER, erroneous bits, improved wear leveling, improved read window budget (RWB), etc.) can be improved in comparison to previous approaches.

As described in more detail herein, the last programmed word line of a PB can be determined. This information can be used to alter a debiasing voltage applied to word lines that were programmed before (inclusive of the last programmed word line) and/or word lines after the last programmed word line (e.g., unprogrammed word lines). In some embodiments, this pulse debiasing scheme can be performed during an erase operation involving the PB. By increasing the debiasing voltage on word line groups (or “segments”) that are not programmed while applying a lesser (e.g., “standard”) debiasing voltage on programed word line segments, the overall functioning of a memory device and/or a memory sub-system in which the memory device operates can be improved in comparison to previous approaches.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, server, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., an SSD controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random-access memory (DRAM) and synchronous dynamic random access memory (SDRAM).

Some examples of non-volatile memory devices (e.g., memory device 130) include NOT-AND(NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130, 140 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLC) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as three-dimensional cross-point arrays of non-volatile memory cells and NAND type memory (e.g., 2D NAND, 3D NAND) are described, the memory device 130 can be based on any other type of non-volatile memory or storage device, such as such as, read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

The memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address, physical media locations, etc.) that are associated with the memory devices 130. The memory sub-system controller 115 can further include host interface circuitry to communicate with the host system 120 via the physical host interface. The host interface circuitry can convert the commands received from the host system into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device 130 and/or the memory device 140.

In some embodiments, the memory device 130 includes local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

As shown in FIG. 1, the memory sub-system 110 can include a data structure 118. As used herein, a “data structure” refers to a specialized format for organizing and/or storing data, which may or may not be organized in rows and columns. Examples of data structures include arrays, files, records, tables, trees, linked lists, hash tables, etc. In some embodiments, the data structure 118 can be configured to store one or more look-up tables that contain predetermined voltage offset ranges that are based on different word line groups of the memory sub-system 110. In some embodiments, the data structure 118 can be accessed during performance of operations related to application of a voltage offset to a word line group to determine a range of voltage offsets that may be applied to a particular word line group of the memory sub-system 110.

The memory sub-system 110 can include debiasing circuitry 113. Although not shown in FIG. 1, so as to not obfuscate the drawings, the debiasing circuitry 113 can include various circuitry to facilitate performance of operations related to a debiasing scheme for partial block erase based on word line groups. In some embodiments, the debiasing circuitry 113 can include special purpose circuitry in the form of an ASIC, FPGA, state machine, and/or other logic circuitry that can allow the debiasing circuitry 113 to orchestrate and/or perform operations described herein involving the memory device 130 and/or the memory device 140.

In some embodiments, the memory sub-system controller 115 includes at least a portion of the debiasing circuitry 113. For example, the memory sub-system controller 115 can include a processor 117 (processing device) configured to execute instructions stored in local memory 119 for performing the operations described herein. In some embodiments, the debiasing circuitry 113 is part of the host system 110, an application, or an operating system.

In some embodiments, the memory sub-system 110, and hence the debiasing circuitry 113, the processor 119, and the memory devices 130/140, can be resident on a mobile computing device such as a smartphone, laptop, or phablet among other similar computing devices. As used herein, the term “mobile computing device” generally refers to a handheld computing device that has a slate or phablet form factor. In general, a slate form factor can include a display screen that is between approximately 3 inches and 5.2 inches (measured diagonally), while a phablet form factor can include a display screen that is between approximately 5.2 inches and 7 inches (measured diagonally). Examples of “mobile computing devices” are not so limited, however, and in some embodiments, a “mobile computing device” can refer to an IoT device or any other type of edge computing device(s).

Further, the debiasing circuitry 113 can be resident on the memory sub-system 110. As used herein, the term “resident on” refers to something that is physically located on a particular component. For example, the debiasing circuitry 113 being “resident on” the memory sub-system 110 refers to a condition in which the hardware circuitry that comprises the debiasing circuitry 113 is physically located on the memory sub-system 110. The term “resident on” can be used interchangeably with other terms such as “deployed on” or “located on,” herein.

In some embodiments, the memory sub-system 110 includes a data structure 122. The data structure 122 can include storage locations (e.g., memory cells, latches, capacitors, etc.) that can be configured to store debiasing voltage trim values (e.g., parameters). Accordingly, the data structure 122 can be referred to herein in the alternative as a “debiasing voltage trim parameter data structure.” The voltage trim values/parameters stored by the data structure 122 are discussed in more detail below, however, these voltage trim values/parameters are generally used to determine a debiasing voltage to be applied to different word line groups. Although illustrated in FIG. 1 as being resident on the memory sub-system controller 115, embodiments are not so limited and the data structure 122 can be part of a memory device (e.g., the memory device 130 and/or the memory device 140) and/or can be located on the memory sub-system 110 externally to the memory sub-system controller 115.

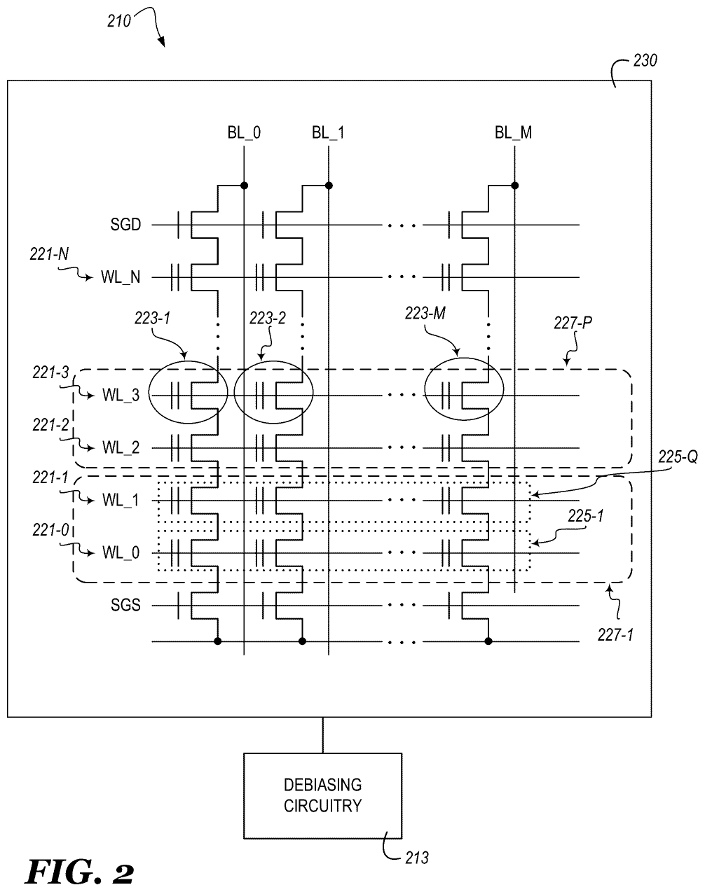

FIG. 2 illustrates an example of a memory device 230 that is experiencing a partial block condition in accordance with some embodiments of the present disclosure. The memory device 230 can be deployed in a memory sub-system 210, which can be analogous to the memory sub-system 110 illustrated in FIG. 1. The memory device 230 can be analogous to the memory device 130 illustrated in FIG. 1, herein, while the debiasing circuitry 213 can be analogous to the debiasing circuitry 113 illustrated in FIG. 1, herein. The memory device 230 and the debiasing circuitry 213 can be included in a computing system 201. As shown in FIG. 2, the memory device 230 includes a plurality of bit lines BL_0, BL_1 to BL_M, a plurality of word lines WL_0 221-0, WL_1 221-2, WL_2 221-2, WL_3 221-3, and WL_N 221-N (referred to for brevity as word lines 221-1 to 221-N), one or more select gate drain components SGD, and one or more select gate source components SGS. The bit lines BL_0, BL_1 to BL_M and the word lines WL_0 221-0 to WL_N 221-N are coupled to a plurality of memory cells 223-1, 223-2 to 223-M (referred to for brevity as “the memory cells 233-1 to 233-M” or simply as “the memory cells 223”). A set of the memory cells that are coupled to a particular word line (e.g., the word line WL_1) can comprise a page 225 of memory cells 223-1 to 223-M. One or more pages 225-1 to 225-Q of memory cells 223-1 to 223-M can comprise a word line group 227-1 to 227-P.

Although the memory cells 223-1 to 223-M are not explicitly shown within one of the pages 225-1 to 225-Q, it will be appreciated that memory cells analogous to the memory cells 223-1 to 223-M are repeated throughout the memory device 230 to form an array of such memory cells. In some embodiments, the memory cells are TLCs and can therefore store 3 bits per cell—one bit in a “lower page,” one bit in an “upper page,” and one bit in an “extra page.” Further, a word line group 227 can consist of one or more word lines, which can include multiple memory cells 223. although the pages 225-1 to 225-Q of memory cells are illustrated in a single word line group 227-1, embodiments are not so limited and greater or fewer than the two explicitly illustrated pages of memory 225-1 to 225-Q can be part of the word line group 227-1. In addition, although the word line group 227-P is not shown as including pages of memory cells 223-1 to 223-M, one of ordinary skill in the art will appreciate that the word line group 227-P would contain at least one page of memory cells 223-1 to 223-M.

The debiasing circuitry 213 can include various circuitry (e.g., one or more processors, controllers, logic circuits, etc.) to perform the operations described herein. The debiasing circuitry 213 can be provided in the form of an application-specific integrated circuit (ASIC) and/or field programmable gate array (FPGA). In some embodiments, the debiasing circuitry 213 can include an instruction set architecture (ISA) such as a reduced instruction set architecture (RISC). In embodiments in which the debiasing circuitry 213 includes a RISC device, the RISC device can include a processing resource that can employ a reduced instruction set architecture (ISA) such as a RISC-V ISA, however, embodiments are not limited to RISC-V ISAs and other processing devices and/or ISAs can be used.

In some embodiments, the debiasing circuitry 213 can dynamically cause application of different debiasing voltages (e.g., during performance of an erase operation) to different word line groups (e.g., the word line group 227-1 and the word line group 227-P) based on whether such word line groups are programmed or unprogrammed. For example, the debiasing circuitry 213 can determine that the word line group 227-1 includes programmed memory cells, and the word line group 227-P contains unprogrammed memory cells. The debiasing circuitry 213 can then provide a first debiasing voltage to the word line group 227-1 and a second debiasing voltage to the word line group 227-P, for example during performance of an erase operation involving blocks of the memory device 230.

In some embodiments, the debiasing voltage applied to programmed word line groups (e.g., the word line group 227-1) can be a lower debiasing voltage value than the debiasing voltage applied to unprogrammed word line groups (e.g., the word line group 227-P). In an illustrative non-limiting example, a debiasing voltage of ˜0.5 Volts (V) can be applied to a programmed word line group while a debiasing voltage of ˜1.0 V can be applied to an unprogrammed word line group. It is noted that the debiasing voltages described herein are generally debiasing voltages relative to a pillar voltage associated with the memory cells 223 (e.g., a pillar voltage associated with a block of memory cells). For example, if the pillar voltage is ˜20.0 V, the illustrative debiasing voltage mentioned above (˜1.0 V) applied to the unprogrammed word lines can yield an overall potential difference of ˜19.0 V, while the illustrative debiasing voltage mentioned above (˜0.5 V) applied to the programmed word lines can yield an overall potential difference of ˜19.5 V across the word lines at issue.

Although generally described herein for simplicity in terms of two debiasing voltages, embodiments are not so limited and any quantity of debiasing voltages can be utilized based on characteristics of the memory device 230 and/or a ratio of programmed word line groups 227-1 to unprogrammed word line groups 227-N. That is, embodiments herein allow for a first debiasing voltage to be applied to a first word line group 227-1 and a second debiasing voltage to be applied to a second word line group 227-P when a quantity of programmed and unprogrammed word lines is roughly equal. However, if other ratios (e.g., if ˜75% of the word lines are programmed and ˜25% are unprogrammed, if ˜10% of the word line are programmed and ˜90% of the word lines are unprogrammed, etc.) of programmed vs. unprogrammed word lines are detected, different debiasing voltages can be used. In addition, embodiments herein can allow for a first debiasing voltage to be applied to portion of programmed word lines, a second debiasing voltage to be applied to a second portion of programmed word lines, a third debiasing voltage to be applied to a first portion of unprogrammed word lines, etc. In some embodiments, trims corresponding to these and other scenarios are stored in the data structures described herein.

As described above, by applying different debiasing voltage to different word lines groups 227 based on whether the word line groups 227 are programmed or unprogrammed, over-erase issues that can arise in previous approaches (particularly over-erase issues that may be exacerbated when partial blocks are utilized and/or over-erase states that can arise as a result of back-to back PB cycling, etc.) can be mitigated while post-cycling data retention (e.g., program-erase cycling, PB cycling, etc.) in comparison to previous approaches and/or overall performance (e.g., a reduction in tPROG, RBER, erroneous bits, improved wear leveling, improved read window budget (RWB), etc.) can be improved in comparison to previous approaches.

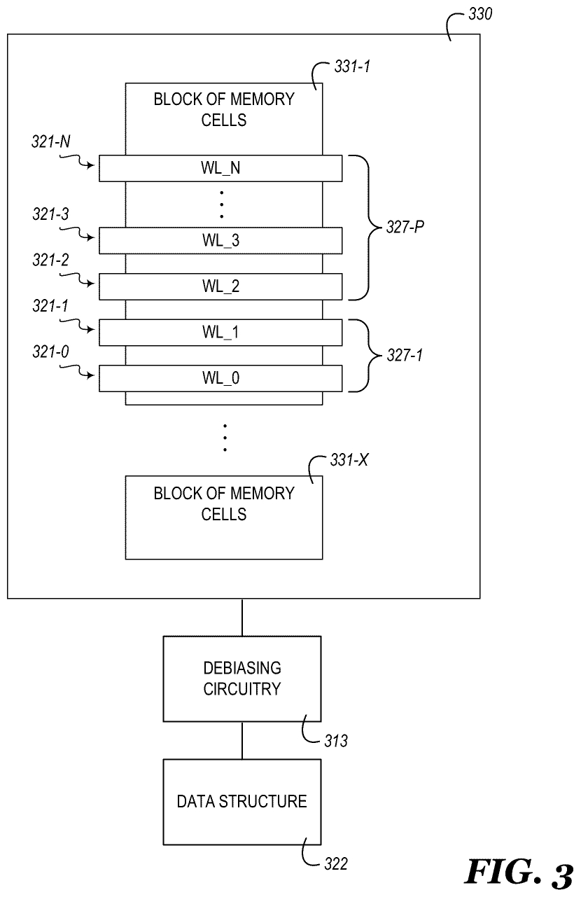

FIG. 3 illustrates another example of a memory device 330 coupled to debiasing circuitry 313 in accordance with some embodiments of the present disclosure. The memory device 330 can be analogous to the memory device 130/230 illustrated in FIG. 1 and FIG. 2, herein, while the debiasing circuitry 313 can be analogous to the debiasing circuitry 113/213 illustrated in FIG. 1 and FIG. 2, herein. The debiasing circuitry 313 is communicatively coupled to a data structure 322, which can be analogous to the data structure 122 illustrated in FIG. 1, herein. As illustrated in FIG. 3, the memory device 330 includes blocks 331-1 to 331-X of memory cells, which are coupled to word lines 321-0, 321-1, 321-2, 321-3, to 321-N (collectively referred to herein as “word lines 321”). The word lines 321-0 to 321-N can be analogous to the word lines 221-0 to 221-N illustrated in FIG. 2.

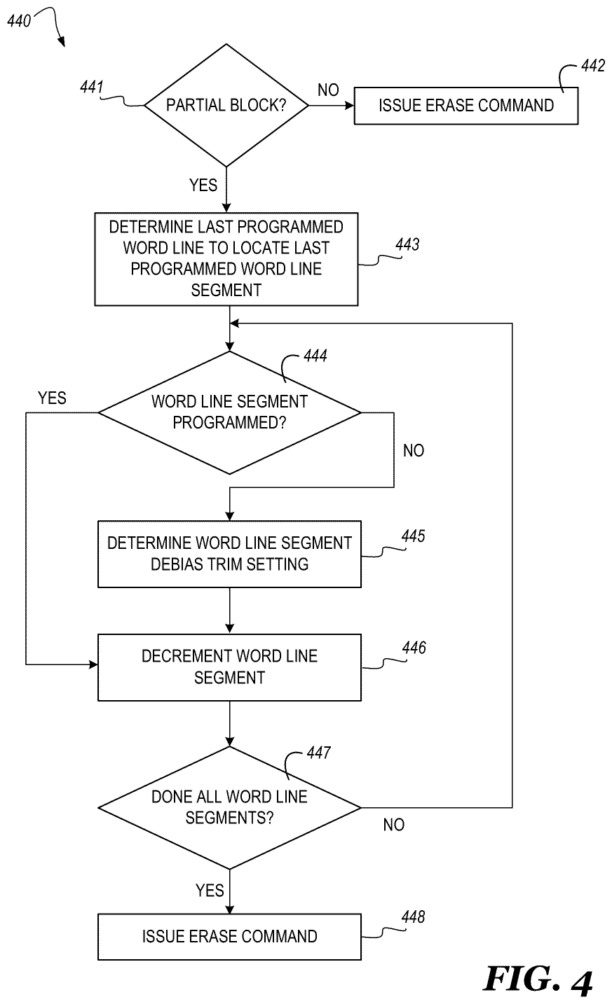

In FIG. 3, two word line groups (327-1 and 327-P) are illustrated for simplicity, however, it will be appreciated that the quantity of word line groups can be increased within the scope of the disclosure. As discussed in more detail in connection with FIG. 4, the word line groups can be determined based on detection of a last programmed word line group. For example, the debiasing circuitry 313 can determine which word lines 321 have been programmed and, once the last programmed word line has been detected, determine that subsequent word lines have not been programmed and are therefore unprogrammed word lines. For example, the debiasing circuitry 313 can determine a last programmed word line associated with the block of memory cells 331 and assign the first status to the first group of word lines or assign the second status to the second group of word lines based on the determined last programmed word line associated with the block of memory cells 331. In some embodiments, the debiasing circuitry 313 can determine the last programmed word line by performing an iterative operation to determine whether data has been written to physically adjacent word lines among the plurality of word lines until a word line that is coupled to memory cells that are unprogrammed is detected. In the illustrative example shown in FIG. 3, the last programmed word line is WL_1 321-1 and the subsequent word lines (e.g., WL_2 321-2, WL_3 321-3, to WL_N 321-N) are therefore unprogrammed word lines.

Based on this determination, the debiasing circuitry 313 (e.g., a processor or processing device) can assign a first status (e.g., a programmed status) to WL_0 321-0 and WL_1 321-1 and group these word lines together in a first word line group 327-1. In addition, the debiasing circuitry 313 can assign a second status (e.g., an unprogrammed status) to WL_2 321-2, WL_3 321-3, to WL_N 321-N and group these word lines together in a second word line group 327-P. That is, the debiasing circuitry 313 can assign the first status to the first group of word lines (e.g., the word line group 327-1) when the first group of word lines are coupled to memory cells that are in a programmed state and assign the second status to the second group of word lines (e.g., the word line group 327-P) when the second group of word lines are coupled to memory cells that are in an unprogrammed state. Moreover, the debiasing circuitry 313 can determine that the block of memory cells 331 is experiencing a partial block condition and assign the first status and/or the second status and/or apply the first debiasing voltage or the second debiasing voltage in response to determining that the block of memory cells 331 is experiencing the partial block condition.

The debiasing circuitry 313 can then apply a first debiasing voltage to the first group of word lines 327-1 based on the first group of word lines being assigned the first status (e.g., the programmed status) and can apply a second debiasing voltage to the second group of word lines based on the second group of word lines being assigned the second status (e.g., the unprogrammed status). In some embodiments, the second debiasing voltage is larger than the first debiasing voltage relative to a voltage applied to a pillar area associated with the block of memory cells (e.g., the block of memory cells 331-1).

Continuing with this non-limiting example, the debiasing circuitry 313 can access debiasing voltage trim information written to a data structure 332 coupled to the debiasing circuitry 313 to determine the first debiasing voltage and/or the second debiasing voltage. In some embodiments, the debiasing circuitry 313 can apply the first debiasing voltage to the first group of word lines (e.g., the word line group 327-1) as part of performance of an operation to erase data written to memory cells coupled to the first group of word lines 327-1 and apply the second debiasing voltage to the second group of word lines (e.g., the word line group 327-P) as part of performance of an operation to erase data written to memory cells coupled to the second group of word lines.

In some embodiments, the debiasing circuitry 313, the memory device 330, and/or the data structure 332 can be resident on a memory sub-system, as shown in FIG. 1. In addition, in some embodiments, the debiasing circuitry 313 can perform the operations described herein during runtime of a computing device (e.g., the computing system 100 illustrated in FIG. 1) in which the debiasing circuitry 313, the memory device 330, and/or the data structure 332 are deployed. That is, in some embodiments, the debiasing circuitry 313 is configured to perform operations related to a debiasing scheme for partial block erase based on word line groups dynamically as the memory device 330 operates “in the field.”

FIG. 4 illustrates an example flow diagram 440 corresponding to a debiasing scheme for partial block erase based on word line groups or “segments,” or word lines in accordance with some embodiments of the present disclosure. At operation 441, a determination is made as to whether a block of memory cells (e.g., one or more of the blocks of memory cells 331-1 to 331-X illustrated in FIG. 3, herein) is experiencing a partial block condition. If the block is not experiencing a partial block condition (i.e., if the block is a full block), the flow proceeds to operation 442 and an erase command to erase the memory cells of the block is issued.

If, however, the block is experiencing the partial block condition, at operation 443, a last programmed word line of the block is determined. In some embodiments, a processor (e.g., the debiasing circuitry 113/213/313 illustrated in FIGS. 1-3, herein) can perform operations to check if word lines coupled to the block are programmed or unprogrammed. In some embodiments, for example, at operation 444, the processor can start at a word line that is known to be programmed (or an adjacent word line where it is not known if the word line is programmed) and iteratively check word lines in a sequential order until the processor locates a word line that is unprogrammed. The processor can then determine that an immediately preceding word line is the past programmed word line as word lines subsequent to this programmed word line will be unprogrammed.

Once the processor locates a word line that is unprogrammed, the flow 440 continues to operation 445, where the processor can determine a debias trim setting for the word line (e.g., for a word line group/segment that the word line is part of, as described above). In some embodiments, the debias trim setting can be retrieved from a data structure such as the data structure 122 illustrated in FIG. 1 and/or the data structure 322 illustrated in FIG. 3, herein. If the processor has not located an unprogrammed word line at operation 444, the flow 440 continues to operation 446 where the word line segment (or word line) is decremented.

At operation 446, a determination can be made as to whether the word lines have been checked to determine whether they are programmed or not. If not, the flow 440 continues back to operation 444 and iteratively repeats until the word lines have been checked. Once the processor has completed checking the word lines, the flow 440 continues to operation 448 and an erase command is issued to the block. As described herein, this erase command will be carried out using different debiasing voltages on word line groups based on whether or not the word lines associated with such word line groups are programmed or unprogrammed.

Although FIG. 4 generally describes a scenario in which the word line segment is decremented, embodiments are not so limited. For example, the word line segment (or word line) can, in addition to, or in the alternative, be incremented depending on the programming sequence. For example, if the word lines are programmed drain to source, the word line segment may be incremented while if the word lines are programmed source to drain, the word line segment may be decremented.

In another illustrative non-limiting example, if a word line group (a “word_line_group_0) includes thirty-one word lines (WL 0 to WL 30) and data is written only until WL 25. In some embodiments, a different debias voltage can be applied to WL 0 to WL 25 than is applied to WL 26 to WL 30, as described herein. Embodiments are not so limited and, as described above, different debias voltages can be applied to programmed and un-programmed word lines within a partial block in addition to, or in the alternative to merely applying different debias voltages to programmed word line groups and un-programmed word line groups.

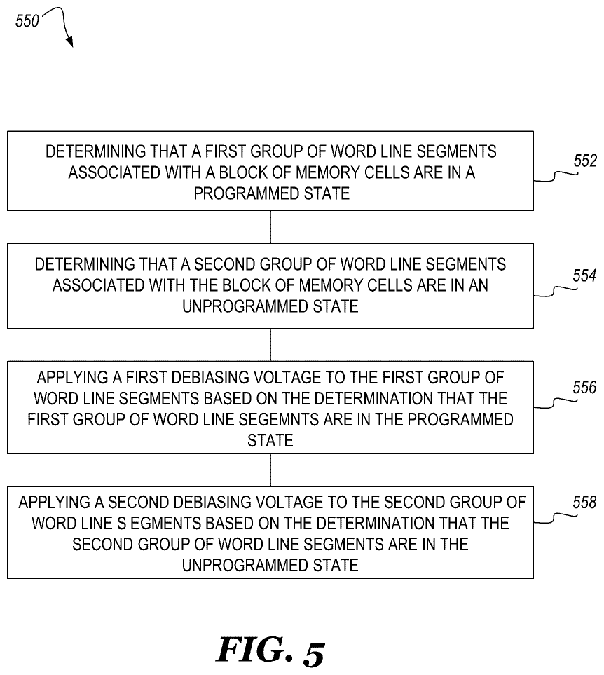

FIG. 5 is a flow diagram corresponding to a method 550 for a debiasing scheme for partial block erase based on word line groups in accordance with some embodiments of the present disclosure. The method 550 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 550 is performed by the debiasing circuitry 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 552, the method 550 includes determining that a first group of word line segments associated with a block of memory cells are in a programmed state. The first group of word line segments can be analogous to a portion of the word line group 327-1 illustrated in FIG. 3 and the block of memory cells can be analogous to the block of memory cells 331-1 illustrated in FIG. 3.

At operation 554, the method 550 includes determining that a second group of word line segments associated with the block of memory cells are in an unprogrammed state. The second group of word line segments can be analogous to a portion of the word line group 327-P illustrated in FIG. 3. In some embodiments, the method 550 includes determining that the block of memory cells is partially programmed as part of determining that the first group of word line segments are in the programmed state and determining that the second group of word line segments are in the unprogrammed state. As described above, in some embodiments, the method 550 includes determining, as part of determining that the first group of word line segments are in the programmed state or determining that the second group of word line segments are in the unprogrammed state, or both, by determining a last programmed word line associated with the block of memory cells.

At operation 556, the method 550 includes applying a first debiasing voltage to the first group of word line segments based on the determination that the first group of word line segments are in the programmed state. At operation 558, the method 550 includes applying a second debiasing voltage to the second group of word line segments based on the determination that the second group of word line segments are in the unprogrammed state. As described above, the second debiasing voltage can be larger than the first debiasing voltage relative to a voltage applied to a pillar area associated with the block of memory cells. In some embodiments, the method 550 includes determining the first debiasing voltage or the second debiasing voltage, or both, based on information written to a debiasing voltage trim parameter data structure, such as the data structure 122 illustrated in FIG. 1 and/or the data structure 322 illustrated in FIG. 3.

In some embodiments, the method 550 includes applying the first debiasing voltage to the first group of word line segments as part of performance of an operation to erase data written to memory cells coupled to the first group of word lines and applying the second debiasing voltage to the second group of word line segments as part of performance of an operation to erase data written to memory cells coupled to the second group of word lines.

In a non-limiting illustrative embodiment, the word line groups can be a predetermined entity with a set quantity of word lines. For example: Suppose there are 100 word lines in a block and there are 6 word line groups. In this scenario, the word line groups (WLGs) can be given as follows: WLG_0=WL_0-WL_5; WLG_1=WL_6-WL_28; WLG_2=WL_29-WL_55; WLG_3=WL_56-WL_78; WLG_4=WL_79-WL_90; and WLG_5=WL_91-WL_99. In one illustrative embodiment, if the WLs up to WL_60 are programmed (e.g., a first unprogrammed WL falls in WLG_3), a first debiasing voltage may be applied to WLG_0-WLG_3 and a second (higher) debiasing voltage to WLG_4 and WLG_5. Even though WLG3 has few WLs in un-programmed state (WL61-WL78).

In another illustrative embodiment using the same example WLGs above, if the WLs up to WL_60 are programmed (e.g., a first unprogrammed WL falls in WLG_3), a first debiasing voltage can be applied up to WL_60 and a second (higher) debiasing voltage can be applied to WL_61 onward (e.g., to WL_61-WL_99). It will, however be appreciated that the quantity of WLs used in the preceding example embodiments is not intended to be limiting and other quantities of WLs and/or WLGs can be utilized without departing from the scope of the disclosure.

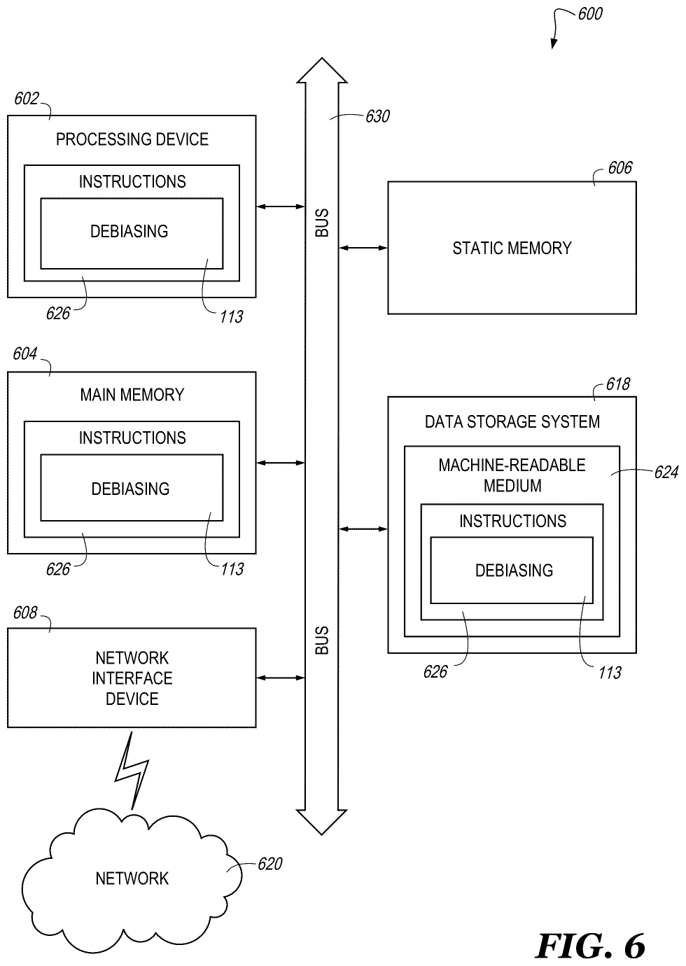

In another non-limiting example, a non-transitory machine-readable storage medium (e.g., the machine-readable medium 624 of FIG. 6) can include instructions (e.g., the instructions 626 of FIG. 6) that, when executed by a processing device (e.g., the debiasing circuitry 113/213/313 of FIGS. 1-3), cause the processing device to determine a last programmed word line associated with a plurality of word lines (e.g., the word lines 221/321 of FIGS. 2-3) of a block of memory cells (e.g., the block of memory cells 331 of FIG. 3), as described above. In some embodiments, the processing device is configured to determine the last programmed word line by performing an iterative operation to determine whether data has been written to physically adjacent word lines among the plurality of word lines until a word line that is coupled to memory cells that are unprogrammed is detected.

The instructions can be further executed by the processor to assign a first status to a first group of word (e.g., the word line group 327-1 illustrated in FIG. 3) lines among the plurality of word lines and assign a second status to a second group of word lines (e.g., the word line group 327-P illustrated in FIG. 3) among the plurality of word lines. In such examples, the first group of word lines includes the last programmed word line and word lines and programmed word lines adjacent to the last programmed word line and the second group of word lines includes unprogrammed word lines adjacent to the last programmed word line, as discussed in connection with FIG. 3.

The instructions can be further executed by the processor to apply a first debiasing voltage to the first group of word lines based on the first group of word lines being assigned the first status and apply a second debiasing voltage to the second group of word lines based on the second group of word lines being assigned the second status. In some embodiments, the processing device can apply the first debiasing voltage to the first group of word lines as part of performance of an operation to erase data written to memory cells coupled to the first group of word lines and apply the second debiasing voltage to the second group of word lines as part of performance of an operation to erase data written to memory cells coupled to the second group of word lines.

As discussed above, the second debiasing voltage can be larger than the first debiasing voltage relative to a voltage applied to a pillar area associated with the block of memory cells. Further, as described above, the processing device can be configured to access debiasing voltage trim information written to a data structure (e.g., the data structure 122 illustrated in FIG. 1 and/or the data structure 322 illustrated in FIG. 3) coupled to the processor to determine the first debiasing voltage and/or the second debiasing voltage.

FIG. 6 is a block diagram of an example computer system 600 in which embodiments of the present disclosure may operate. For example, FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the debiasing circuitry 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 619, which communicate with each other via a bus 630.

The processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 908 to communicate over the network 620.

The data storage system 619 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In some embodiments, the instructions 626 include instructions to implement functionality corresponding to debiasing circuitry (e.g., the debiasing circuitry 113 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method, comprising:
determining that a first group of word line segments associated with a block of memory cells are in a programmed state;
determining that a second group of word line segments associated with the block of memory cells are in an unprogrammed state;
applying a first debiasing voltage to the first group of word line segments based on the determination that the first group of word line segments are in the programmed state; and
applying a second debiasing voltage to the second group of word line segments based on the determination that the second group of word line segments are in the unprogrammed state.

2. The method of claim 1, wherein the second debiasing voltage is larger than the first debiasing voltage relative to a voltage applied to a pillar area associated with the block of memory cells.

3. The method of claim 1, further comprising:
applying the first debiasing voltage to the first group of word line segments as part of performance of an operation to erase data written to memory cells coupled to the first group of word lines; and
applying the second debiasing voltage to the second group of word line segments as part of performance of an operation to erase data written to memory cells coupled to the second group of word lines.

4. The method of claim 1, further comprising determining that the block of memory cells is partially programmed as part of determining that the first group of word line segments are in the programmed state and determining that the second group of word line segments are in the unprogrammed state.

5. The method of claim 1, further comprising determining, as part of determining that the first group of word line segments are in the programmed state or determining that the second group of word line segments are in the unprogrammed state, or both, by determining a last programmed word line associated with the block of memory cells.

6. The method of claim 1, further comprising determining the first debiasing voltage or the second debiasing voltage, or both, based on information written to a debiasing voltage trim parameter data structure.

7. An apparatus, comprising:
a block of memory cells coupled to a plurality of word lines; and
a processor coupled to the block of memory cells, wherein the processor is configured to:
assign a first status to a first group of word lines among the plurality of word lines;
assign a second status to a second group of word lines among the plurality of word lines;
apply a first debiasing voltage to the first group of word lines based on the first group of word lines being assigned the first status; and
apply a second debiasing voltage to the second group of word lines based on the second group of word lines being assigned the second status.

8. The apparatus of claim 7, wherein the processor is configured to:
assign the first status to the first group of word lines when the first group of word lines are coupled to memory cells that are in a programmed state; and
assign the second status to the second group of word lines when the second group of word lines are coupled to memory cells that are in an unprogrammed state.

9. The apparatus of claim 7, wherein the second debiasing voltage is larger than the first debiasing voltage relative to a voltage applied to a pillar area associated with the block of memory cells.

10. The apparatus of claim 7, wherein the processor is configured to:
apply the first debiasing voltage to the first group of word lines as part of performance of an operation to erase data written to memory cells coupled to the first group of word lines; and
apply the second debiasing voltage to the second group of word lines as part of performance of an operation to erase data written to memory cells coupled to the second group of word lines.

11. The apparatus of claim 7, wherein the processor is configured to:
determine a last programmed word line associated with the block of memory cells; and
assign the first status to the first group of word lines or assign the second status to the second group of word lines based on the determined last programmed word line associated with the block of memory cells.

12. The apparatus of claim 11, wherein the processor is configured to determine the last programmed word line by performing an iterative operation to determine whether data has been written to physically adjacent word lines among the plurality of word lines until a word line that is coupled to memory cells that are unprogrammed is detected.

13. The apparatus of claim 7, wherein the processor is configured to determine that the block of memory cells is experiencing a partial block condition prior to:
assignment of the first status, the second status, or both; or
application of the first debiasing voltage or the second debiasing voltage, or both.

14. The apparatus of claim 7, wherein the processor is configured to access debiasing voltage trim information written to a data structure coupled to the processor to determine the first debiasing voltage or the second debiasing voltage, or both.

15. The apparatus of claim 7, wherein the block of memory cells and the processor are resident on a solid state drive.

16. A non-transitory machine-readable storage medium comprising instructions that, when executed by a processing device, cause the processing device to:
determine a last programmed word line associated with a plurality of word lines of a block of memory cells;
assign a first status to a first group of word lines among the plurality of word lines, wherein the first group of word lines includes the last programmed word line and word lines and programmed word lines adjacent to the last programmed word line;
assign a second status to a second group of word lines among the plurality of word lines, wherein the second group of word lines includes unprogrammed word lines adjacent to the last programmed word line;
apply a first debiasing voltage to the first group of word lines based on the first group of word lines being assigned the first status; and
apply a second debiasing voltage to the second group of word lines based on the second group of word lines being assigned the second status.

17. The non-transitory machine-readable storage medium of claim 16, wherein the processing device is configured to determine the last programmed word line by performing an iterative operation to determine whether data has been written to physically adjacent word lines among the plurality of word lines until a word line that is coupled to memory cells that are unprogrammed is detected.

18. The non-transitory machine-readable storage medium of claim 16, wherein the processing device is configured to:
apply the first debiasing voltage to the first group of word lines as part of performance of an operation to erase data written to memory cells coupled to the first group of word lines; and
apply the second debiasing voltage to the second group of word lines as part of performance of an operation to erase data written to memory cells coupled to the second group of word lines.

19. The non-transitory machine-readable storage medium of claim 16, wherein the second debiasing voltage is larger than the first debiasing voltage relative to a voltage applied to a pillar area associated with the block of memory cells.

20. The non-transitory machine-readable storage medium of claim 16, wherein the processing device is configured to access debiasing voltage trim information written to a data structure coupled to the processor to determine the first debiasing voltage or the second debiasing voltage, or both.
